(19) United States
(12) Patent Application Publication
(10) Pub. No.: US 2009/0324401 A1
(43) Pub. Date: Dec. 31, 2009

(54) ARTICLE HAVING A PROTECTIVE COATING AND METHODS

(75) Inventor: Eklavya Calla, Karnataka (IN)

Correspondence Address: SUTHERLAND ASBILL & BRENNAN LLP, 999 PEACHTREE STREET, N.E., ATLANTA, GA, 30309, US

(73) Assignee: GENERAL ELECTRIC COMPANY, Schenectady, NY (US)

(21) Appl. No.: 12/114,411

(22) Filed: May 2, 2008

(51) Int. Cl. F01D 9/02; B32B 3/10; B22D 23/00; B05D 1/08; C23C 16/00; C23C 14/34; B05D 3/00; F01D 5/28

(52) U.S. Cl. 415/200; 428/172; 164/76.1; 427/446; 427/248.1; 204/192.12; 427/457; 416/241 R

(57) ABSTRACT

The article comprises a substrate having a first surface, a plurality of elements extending from the first surface, and a protective coating disposed between at least a portion of the plurality of elements, on at least a portion of the plurality of elements, or both. The plurality of elements are integral with the substrate. A method for applying a protective coating onto an article is also provided.

### TECHNICAL FIELD

This disclosure generally relates to articles having a protective coating.

### BACKGROUND OF THE INVENTION

In various applications, such as in turbine blade or nozzle airfoil applications, metals, ceramics, and/or ceramic composites may be used to provide a protective coating, such as for insulation, onto a substrate. However, such materials may have low adhesion on particular materials, such as certain metallic materials, which can lead to spallation and/or failure. In addition, ceramics and/or ceramic composite materials may fail due to formation of cracks and subsequent propagation of the cracks because of brittleness of the materials.

Accordingly, there is a need for improved methods for providing a protective coating, such as metal or ceramic insulation, to a substrate in need of such protection.

### SUMMARY OF THE INVENTION

This disclosure provides an article comprising a substrate having a first surface, a plurality of elements extending from the first surface, and a protective coating disposed between at least a portion of the plurality of elements, on at least a portion of the plurality of elements, or both. The plurality of elements are integral with the substrate.

This disclosure also provides a method for applying a protective coating onto an article comprising a substrate having a first surface. The method comprises providing a plurality of elements extending from the first surface and disposing a protective coating between at least a portion of the plurality of elements, on at least a portion of the plurality of elements, or both. The plurality of elements are integral with the substrate.

Other objects, features, and advantages of this invention will be apparent from the following detailed description, drawings, and claims.

### BRIEF DESCRIPTION OF DRAWINGS

FIG. 1 illustrates a front view of a turbine blade airfoil comprising a plurality of elements made in accordance with an embodiment of the present disclosure.

FIGS. 2A-2B illustrate cross-sectional views of portions of turbine blade airfoils comprising a plurality of elements on a first surface and a protective coating disposed on and between the plurality of elements made in accordance with embodiments of the present disclosure.

FIG. 3 illustrates a method for applying a protective coating to an article in accordance with an embodiment of the present disclosure.

### DETAILED DESCRIPTION OF EMBODIMENTS

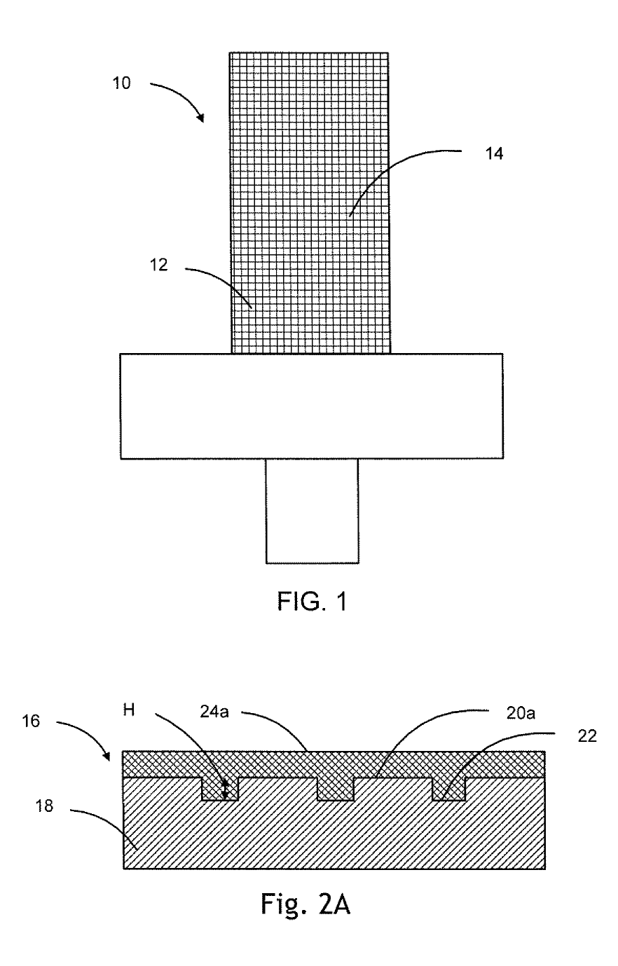

As summarized above this disclosure encompasses an article and a method of applying a protective coating onto an article. Embodiments of the article and embodiments of the method for applying a protective coating onto the article are described below and illustrated in FIGS. 1-3. Though FIGS. 1-3 are illustrated and described with reference to embodiments for a turbine blade airfoil, it should be understood that any article (e.g., turbine nozzle airfoil or any article used in a high temperature environment) having a substrate requiring a protective coating may likewise be employed or be made by alternate embodiments of the present disclosure.

FIG. 1 illustrates a turbine blade airfoil 10 including a substrate 12 having first surface. A plurality of elements 14 extend from the first surface. In some embodiments, the substrate 12 may comprise an alloy (e.g., a super alloy) or a metal. Suitable materials for use in embodiments of the substrate 12 include, but are not limited to, tungsten, tantalum, carbon, or combinations thereof. It should be understood, however, that a person of ordinary skill in the art would be able to select the appropriate substrate for the desired application.

As illustrated in FIG. 1, the plurality of elements 14 comprise a plurality of blocks extending from the substrate 12. The plurality of elements 14 are integral to the substrate 12 and comprises the same material as the substrate. In some embodiments, the plurality of elements 14 may comprise a composite having a material gradient along a direction substantially perpendicular to the first surface (i.e., is graded). For example, the plurality of elements 14 may comprise a metal composite where the content of a first metal as compared to the composition of the remainder of the composite in the plurality of elements increases progressively in a direction moving away from the substrate 12, or vice versa (i.e., the amount of the first metal varies in a direction substantially perpendicular to the first surface). In such an example, the substrate 12 may comprise the same metal as in the metal composite of the plurality of elements 14 and the metal composite may additionally comprise a second metal or a non-metal component in the remainder of the composite.

As used herein, the term “element” (or “segment”) refers to any structure extending from the substrate, at least in part away from the first surface of the substrate. In alternate embodiments, the plurality of elements 14 may pointed, planar, or any other shape suitable to provide an anchoring point for a protective coating to be bonded. In particular embodiments, a planar or a blunted element shape may provide greater surface area for the protective coating to be applied. In alternate embodiments, each of the plurality of elements 14 may comprise a shape selected from the group consisting of a cube, a cylinder, a hemisphere, a sphere, cone, a pyramid and any other three-dimensional shape having a polygonal or curved cross-section. In some embodiments, at least one of the plurality of elements 14 may have a shape different from the remainder of the plurality of elements. However, it should be understood that a person of ordinary skill in the art would be able to select the appropriate shapes of the plurality of elements 14 for the desired application. For example, the profile of each of the plurality of elements 14 could be shaped to match the profile of the first surface of the substrate 12.

As used herein, the term “element size” refers to any dimension of the elements which may be used to indicate the largest feature of each element. For example, the element size may refer to the length of a side of a block-shaped element. In another instance, the element size may refer to the diameter of a hemispherical or cylindrical element. In some embodiments, at least one of the plurality of elements 14 has an element size of about 0.1 centimeters to about 25 centimeters. In other embodiments, at least one of the plurality of elements 14 has an element size of about 0.2 centimeters to about 8 centimeters. In still other embodiments, the at least one of the plurality of elements 14 has an element size of about 0.5 centimeters to about 5 centimeters.

In some embodiments, at least one of the plurality of elements 14 has an element height of about 1 micron to about 50,000 microns. In other embodiments, at least one of the plurality of elements 14 has an element height of about 2 microns to about 25,000 microns. In still other embodiments, at least one of the plurality of elements 14 has an element height of about 2 microns to about 20,000 microns. As used herein, the term “height” refers to the distance measured along a path substantially perpendicular to the first surface from the first surface to a portion of the element furthest away from the first surface.

It should be understood that any appropriate shape and size for the plurality of elements 14 may be chosen by a person of ordinary skill in the art based on the design of the turbine blade airfoil 10 and the protective coating to be used.

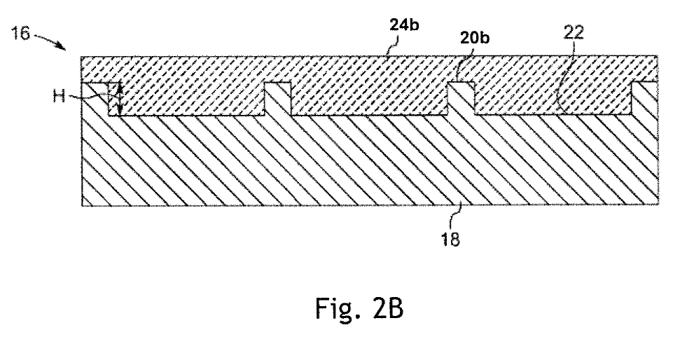

FIG. 2A illustrates a cross-sectional view of a portion of turbine blade airfoil 16 having a substrate 18. The substrate 18 comprises a plurality of elements 20a on a first surface 22 and a protective coating 24a disposed on and between the plurality of elements. The substrate 18 and the plurality of elements 20a may be similar to the substrate 12 and the plurality of elements 14 described above. The plurality of elements 20a have an element height H.

FIG. 2B illustrates another embodiment of a portion of turbine blade airfoil 16, where the plurality of elements 20b have a different shape. Like elements in FIGS. 2A and 2B are numbered with like numerals.

As illustrated in FIGS. 2A-B, the protective coating 24a, 24b is disposed both between and on top of the plurality of elements 20a, 20b. Thus, the exterior of the turbine blade airfoil 16 may appear to be composed of the protective coating 24a, 24b or have a protective coating sheath covering its substrate 18 such that the plurality of elements 20a, 20b is not visible or easily discernable. In alternate embodiments (not shown), the protective coating 24a, 24b may have a surface contour substantially the same as that of the first surface 22 having the plurality of elements 20a, 20b (e.g., when the protective coating is vapor deposited onto the first surface and the plurality of elements). In alternate embodiments, the protective coating 24a, 24b may be disposed between at least a portion of the plurality of elements 20a, 20b. In other embodiments, the protective coating 24a, 24b may be disposed on at least a portion of the plurality of elements 20a, 20b. In some embodiments, the protective coating layer 24a, 24b may cover all of the plurality of elements 20a, 20b to provide insulation to the substrate 18.

Embodiments of the protective coating 24a, 24b may comprise a ceramic, a ceramic composite, a ceramic-metal composite (e.g., cermet), an alloy (e.g., a superalloy), a metal, or any other material which improves the insulation property or any other property which improves the function or extends the life of the turbine blade airfoil 16. Suitable materials for use in embodiments of the protective coating 24a, 24b include, but are not limited to, yttria stabilized zirconia, alumina, aluminum phosphate, aluminosilicate, mullite, NiCrAlY, MCrAlD, or combinations thereof. Embodiments of MCRAlD are such that M may be selected from the group consisting of nickel, cobalt, and iron, Cr is chromium, Al is aluminum, and D may be selected from the group consisting of yttrium, silicon, zirconium, tantalum, hafnium titanium, boron, carbon, and combinations thereof.

As illustrated in FIGS. 2A-2B, the protective coating 24a, 24b comprises one coating layer. In alternate embodiments, the protective coating 24a, 24b may comprise more than one coating layer. For example, the protective coating 24a, 24b may comprise a first coating layer comprising a thermal insulation material and a second coating layer comprising a wear resistant material. In one embodiment, the thermal insulation material comprises yttria stabilized zirconia. In other embodiments, the wear resistant material comprises alumina.

In other embodiments, the protective coating 24a, 24b may comprise a composite having a material gradient along a direction substantially perpendicular to the first surface (i.e., is graded). For example, the protective coating 24a, 24b may comprise a ceramic-metal composite where the metal content in the protective coating increases progressively in a direction moving away from the substrate 18, or vice versa. In such an example, the substrate 18 may comprise the same metal as in the ceramic-metal composite.

In particular embodiments, the protective coating may comprise multiple layers. For example, the protective coating may comprise a metal layer on and between the plurality of elements and a ceramic layer on the metal layer, where the metal layer may function as a bond coating or corrosion protection coating. In some embodiments, the outermost layer (i.e., layer most distal the first surface) of the protective coating may comprise ceramic or cernet for use of the article at temperatures of 1200° C. and greater.

In some embodiments, the turbine blade airfoil 16 having the protective coating 24a, 24b may be used in firing temperatures between about 1100° C. to about 1800° C. In other embodiments, the turbine blade airfoil 16 having the protective coating 24a, 24b may be used in firing temperatures between about 1200° C. to about 1800° C. In still other embodiments, the turbine blade airfoil 16 having the protective coating 24a, 24b may be used in firing temperatures between about 1250° C. to about 1650° C.

In alternate embodiments (not shown), the turbine blade airfoil may further comprise a bond coating disposed adjacent to and between the protective coating and at least a portion of the plurality of elements. In some embodiments, the bond coating comprises MCrAID, and wherein M is selected from the group consisting of nickel, cobalt, and iron, Cr is chromium, Al is aluminum, and D is selected from the group consisting of yttrium, silicon, zirconium, tantalum, hafnium titanium, boron, carbon, and combinations thereof.

In some embodiments, the bond coat may have a thickness between about 1 micron and about 1500 microns. In other embodiments, the bond coat may have a thickness between about 10 microns and about 500 microns. In still other embodiments, the bond coat may have a thickness between about 25 microns and about 250 microns.

In one embodiment, the turbine blade airfoil 16 may comprise a bond coat of NiCrAlY having a thickness of about 100 microns and a graded protective coating. The protective coating has a first coating layer disposed on top of the bond coat comprising 10 wt % ceramic and 90% wt NiCrAlY, a second coating layer comprising 25 wt % ceramic and 75 wt % NiCrAlY, third coating layer of 50 wt % ceramic and 50 wt % NiCrAlY, fourth coating layer of 75% ceramic and 25 wt % NiCrAlY and a fifth coating layer of 100 wt % ceramic.

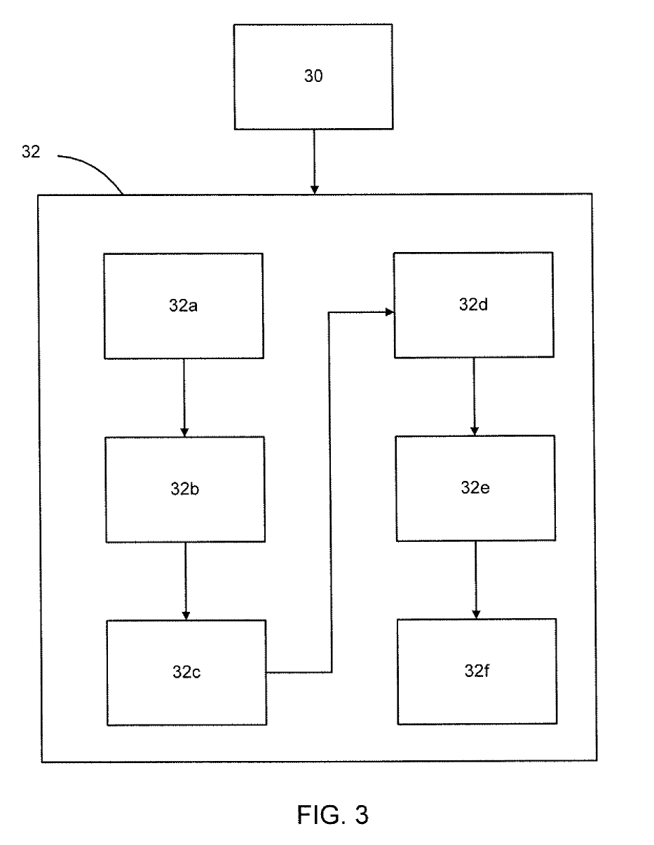

FIG. 3 illustrates a method for applying a protective coating to an article comprising a substrate and a first surface. The article, substrate, and protective coating may be similar to the articles, substrates, and protective coatings described above.

In the first step 30, a plurality of elements extending from the first surface are provided. The plurality of elements are integral with the substrate. Suitable techniques for providing the plurality of elements include, but are not limited to, casting the substrate with the plurality of elements (i.e., forming plurality of elements during the forming of the article substrate).

The second step 32 comprises disposing a protective coating between at least a portion of the plurality of elements, on at least a portion of the plurality of elements, or both. In step 32, the step of disposing comprises slip/slurry/tape casting of a ceramic protective coating. In step 32a, a ceramic slurry is prepared. In step 32b, the ceramic protective coating is poured/cast onto the plurality of elements. In step 32c, the ceramic protective coating is cured/dried. In step 32d, a ceramic binder may be removed if present. In step 32e, the ceramic protective coating is sintered at a temperature between about 800° C. to about 1800° C. In alternate embodiments, the ceramic protective coating may be sintered at a temperature between about 1000° C. to about 1700° C. or at a temperature between about 1100° C. to about 1650° C. In step 32f, the ceramic protective coating is finished by, for example, cleaning, polishing, or both.

Other suitable techniques for disposing the protective coating include, but are not limited to, thermal spraying, plasma spraying, vacuum plasma spraying, flame spraying, high velocity spraying, cold gas dynamic spraying, laser desposition chemical vapor deposition, physical vapor deposition, electron beam physical vapor deposition (EBPVD), cold pressing, sintering, hot isostatic pressing, solgel processing, metallization, combinations thereof or any other method suitable for depositing the protective coating material. For example, the step of disposing 32 may comprise EBPVD followed by plasma spraying another coating layer on top of the EBPVD coating layer. Examples of metallization steps suitable for use in embodiments of step 32 include, but are not limited to, chromizing, aluminizing, or combinations thereof.

In an alternate embodiment, a first coating layer having a thickness between 5 microns to about 500 microns may be applied by plasma spraying or EBPVD to provide an underlayer and some amount of insulating and/or wear and erosion protection before one or more of the methods described above is used to dispose a second coating layer on the first coating layer.

An optional step (not shown) may comprise disposing a bond coating disposed adjacent to and between the protective coating and at least a portion of the plurality of elements. The bond coating may be similar to the bond coating described above. Suitable techniques for disposing the bond coating include, but are not limited to, casting, thermal spraying, plasma spraying, vacuum plasma spraying, flame spraying, high velocity spraying, laser disposition chemical vapor deposition, physical vapor deposition, electron beam physical vapor deposition, metallization, combinations thereof or any other method suitable for depositing the bond coating material. Examples of other suitable methods for disposing a bond coating can be found in co-owned U.S. Pat. No. 6,497,758, which is incorporated herein by references in its entirety.

Without being bound by theory, it is believed that embodiments of the plurality of elements provide anchoring points which improve the strength of the protective coating. In addition, the plurality of elements improve the adhesion of the protective coating to the first surface of the substrate. For example, adhesion of ceramics and/or ceramic composites to superalloy substrates may be improved by use of embodiments the plurality of elements disclosed herein. Furthermore, use of embodiments the plurality of elements can reduce the tendency of cracking in the protective coating and arrest or reduce the growth of any crack that may develop in the protective coating. Thus, failure and/or spallation could be localized in a small region, resulting a longer life for the article, better life prediction of the article, possibly higher firing temperatures, improved efficiency, and a better overall article. Furthermore, articles produced according to methods of the present disclosure may be easier to repair when one or more elements or portions of the coatings on or between the elements are damaged since the damage is localized.

It should be apparent that the foregoing relates only to the preferred embodiments of the present application and that numerous changes and modifications may be made herein by one of ordinary skill in the art without departing from the generally spirit and scope of the invention as defined by the following claims and the equivalents thereof.

We claim:

1. An article comprising:
a substrate having a first surface;
a plurality of elements extending from the first surface, the plurality of elements being integral with the substrate; and
a protective coating disposed between at least a portion of the plurality of elements, on at least a portion of the plurality of elements, or both.

2. The article of claim 1, wherein the substrate comprises an alloy or a metal.

3. The article of claim 1, wherein the protective coating comprises a ceramic, a ceramic composite, a ceramic-metal composite, an alloy, or a metal.

4. The article of claim 1, wherein the protective coating comprises yttria stabilized zirconia, alumina, aluminum phosphate, aluminosilicate, NiCrAlY, or mullite.

5. The article of claim 1, wherein the protective coating comprises a first coating layer and a second coating layer.

6. The article of claim 5, wherein the first coating layer comprises a thermal insulation material and the second coating layer comprises a wear resistant material.

7. The article of claim 6, wherein the thermal insulation material comprises yttria stabilized zirconia and the wear resistant material comprises alumina.

8. The article of claim 1, wherein the protective coating comprises a composite having a material gradient along a direction substantially perpendicular to the first surface.

9. The article of claim 1, wherein the plurality of elements comprise a shape selected from the group consisting of a block, a cube, a cylinder, a hemisphere, a sphere, cone, and a pyramid.

10. The article of claim 1, wherein at least one of the plurality of elements has an element size of about 0.1 centimeters to about 25 centimeters.

11. The article of claim 1, wherein at least one of the plurality of elements has an element height of about 1 micron to about 50000 microns.

12. The article of claim 1, further comprising a bond coating disposed adjacent to and between the protective coating and the at least a portion of the plurality of elements.

13. The article of claim 12, wherein the bond coating comprises MCrAlD, and wherein M is selected from the group consisting of nickel, cobalt, and iron, Cr is chromium, Al is aluminum, and D is selected from the group consisting of yttrium, silicon, zirconium, tantalum, hafnium titanium, boron, carbon, and combinations thereof.

14. The article of claim 1, wherein the article comprises a turbine blade airfoil or turbine nozzle airfoil.

15. A method for applying a protective coating onto an article comprising a substrate having a first surface, the method comprising:
providing a plurality of elements extending from the first surface, the plurality of elements being integral with the substrate; and
disposing a protective coating between at least a portion of the plurality of elements, on at least a portion of the plurality of elements, or both.

16. A method the method of claim 15, wherein the step of providing comprises casting the article comprising the substrate having the first surface with a plurality of elements integral with the substrate.

17. The method of claim 15, wherein the step of disposing comprises casting, thermal spraying, plasma spraying, vacuum plasma spraying, flame spraying, high velocity spraying, laser disposition, chemical vapor deposition, physical vapor deposition, electron beam physical vapor deposition, metallization, cold pressing, sintering, hot isostatic pressing, solgel processing, or combinations thereof.

18. The method of claim 15, wherein the plurality of elements comprise a shape selected from the group consisting of a block, a cube, a cylinder, a hemisphere, a sphere, and a pyramid.

19. The method of claim 15, wherein at least one of the plurality of elements has an element size of about 0.1 centimeters to about 25 centimeters.

20. The method of claim 15, wherein the article comprises a turbine blade airfoil or turbine nozzle airfoil.
